(19) United States
(12) Patent Application Publication
(10) Pub. No.: US 2016/0225520 A1
(43) Pub. Date: Aug. 4, 2016

(54) DEVICE AND METHOD FOR RELEASING A MAGNETIC CORE MOUNTED AROUND A CURRENT CARRYING ELECTRIC CONDUCTOR

(71) Applicant: ELECTRICAL GRID MONITORING LTD., YAVNE (IL)

(72) Inventor: EYAL MIRON, HOD-HASHARON (IL)

(21) Appl. No.: 14/953,348

(22) Filed: Nov. 29, 2015

Related U.S. Application Data
(60) Provisional application No. 62/110,637, filed on Feb. 2, 2015.

(51) Int. Cl. H01F 38/30

(52) U.S. Cl. CPC H01F 38/30; H01F 2038/305

(57) ABSTRACT

A device and a method for demounting a magnetic permeable core mounted around an electric conductor carrying electric current, the device including the core including at least two parts closed around the electric conductor, a secondary coil of electric wire wrapped around at least one part of the core, the coil having two terminals, each at one end of the coil, and a switch, electrically coupled to the two terminals, the switch being operative, when closed, to maintain a short circuit of the coil upon demand, where mounting the device on the electric conductor includes closing the two parts of the core to around the electric conductor while the switch is open, and where demounting the device from the electric conductor includes closing the switch to disengage the two parts of the core.

### CROSS-REFERENCE TO RELATED APPLICATIONS

This application claims the benefit of U.S. Provisional Patent Application No. 62/110,637, filed Feb. 2, 2015, the disclosure of which is incorporated herein by reference in its entirety.

### FIELD

The invention relates to electricity, and more particularly, to using a magnetic core around a conductor carrying a heavy duty electrical current.

### BACKGROUND

The use of a magnetic core around a conductor carrying an electric current is known in the art. It is known that a (primary) conductor carrying an electric current induces a magnetic field around the conductor, and that a core having high magnetic permeability may harvest the induced magnetic field and further transfer it to a (secondary) conductive wire wound around the core. This arrangement is used to harvest electric power from the current in the primary conductor, to sense and measure the electric current in the primary conductor, etc. The arrangement may be used also to induce an electric signal from the secondary winding into the primary winding such as in power line communication (PLC). The magnetic flux flowing in the permeable core causes magnetism which holds components of the core together. This may cause mechanical difficulties when mounting or dismounting the core in the proximity of a (primary) conductor carrying a high (heavy-duty) electric current. There is thus a need for addressing these and/or other issues associated with the prior art.

### SUMMARY

According to one aspect of the present invention there is provided a device including a core including at least two parts, the two parts being operative to close the core around an electric conductor passing there through, a coil of electric wire wrapped around at least one part of the core, the coil including two terminals, each at one end of the coil, and a switch, electrically coupled to the two terminals, the switch being operative to provide a short circuit of the coil upon demand, where mounting the device on the electric conductor includes closing the two parts of the core around the electric conductor while the switch is open, and where demounting the device from the electric conductor includes closing the switch to enable the two parts of the core to disengage from each other.

According to another aspect of the present invention there is provided a device where the demounting of the core from the electric conductor is operative while the electric conductor carries electric current.

According to still another aspect of the present invention there is provided a device where the core is made of a material selected from at least one of: iron, a magnetic permeable material, amorphous metals, and magnetic alloy.

According to yet another aspect of the present invention there is provided a device where at least one of the core and the coil is operative to perform at least one of: measuring electric current via the coil, measuring current in the electric conductor, supplying electric power to an electric device, the electric power being drawn from the magnetic field of the electric conductor, and inducing an electronic signal into the electric conductor.

Further according to another aspect of the present invention there is provided a device where the coil is a plurality of coils mounted on the core, and where the switch is electrically coupled to the terminals of at least one coil of the plurality of coils.

Still further according to another aspect of the present invention there is provided a device where the coil is a plurality of coils mounted on the core, and where the switch is electrically coupled to the terminals of all the coils of the plurality of coils.

Yet further according to another aspect of the present invention there is provided a device where the coil is a plurality of coils mounted on the core, and additionally including a plurality of coils, where each of the coils is electrically coupled to the terminals of a respective coil of the plurality of coils.

Even further according to another aspect of the present invention there is provided a method for demounting a device mounted on an electric conductor carrying electric current, the device being operative to provide electric current from magnetic field of the electric conductor, the method providing the device including a core including at least two parts, the two parts being operative to close the core around an electric conductor passing there through, a coil of electric wire wrapped around at least one part of the core, the coil including two terminals, each at one end of the coil, and a switch, electrically coupled to the two terminals, the switch being operative to provide a short circuit of the coil upon demand. The method further including mounting the device on the electric conductor includes by closing the two parts of the core to form a ring around the electric conductor while the switch is open, and demounting the device from the electric conductor including closing the switch to enable the two parts of the core to disengage from each other.

Unless otherwise defined, all technical and scientific terms used herein have the same meaning as commonly understood by one of ordinary skill in the art to which this invention belongs. The materials, methods, and examples provided herein are illustrative only and not intended to be limiting. Except to the extent necessary or inherent in the processes themselves, no particular order to steps or stages of methods and processes described in this disclosure, including the FIGURE, is intended or implied. In many cases the order of process steps may vary without changing the purpose or effect of the methods described.

### BRIEF DESCRIPTION OF THE DRAWINGS

Embodiments of the invention are herein described, by way of example only, with reference to the accompanying drawings. With specific reference now to the drawings in detail, it is stressed that the particulars shown are by way of example and for purposes of illustrative discussion of several embodiments of the present invention only, and are presented in order to provide what is believed to be a useful and readily understood description of the principles and conceptual aspects of the invention. In this regard, no attempt is made to show structural details of the invention in more detail than is necessary for an understanding of the invention, the description taken with the drawings making apparent to those skilled in the art how the several forms of the invention may be embodied in practice. In the drawings:

FIG. 1 is a simplified illustration of a device including a two-part core for mounting on an electric conductor, a coil, or winding around the core, and a demounting switch for disengaging the core, in accordance with one embodiment.

### DETAILED DESCRIPTION

The present embodiments comprise a device and a method for mounting a magnetic core around a current carrying conductor, and demounting the core while electric current flows through the conductor. Particularly, the core is made of a magnetic permeable material. The principles and operation of the mounting and demounting device and method according to the various embodiments presented herein may be better understood with reference to the following drawings and accompanying description.

Before explaining at least one embodiment in detail, it is to be understood that the embodiments is not limited in its application to the details of construction and the arrangement of the components set forth in the following description or illustrated in the drawings, and the embodiments may be practiced or carried out in various ways. Also, it is to be understood that the phraseology and terminology employed herein is for the purpose of description and should not be regarded as limiting.

In this document, an element of a drawing that is not described within the scope of the drawing and is labeled with a numeral that has been described in a previous drawing has the same use and description as in the previous drawings. Similarly, an element that is identified in the text by a numeral that does not appear in the drawing described by the text, has the same use and description as in the previous drawings where it was described.

The drawings in this document may not be to any scale. Different Figs. may use different scales and different scales can be used even within the same drawing, for example different scales for different views of the same object or different scales for the two adjacent objects.

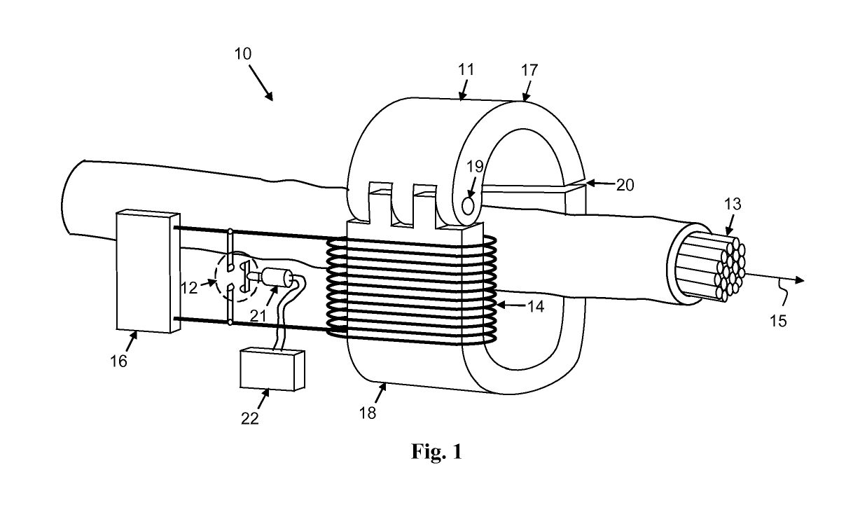

FIG. 1 is a simplified illustration of a power harvesting device 10 including a core 11 and a demounting switch 12, according to one embodiment of the present invention.

As shown in FIG. 1, a first (primary) electric conductor 13 carrying electric current is surrounded by core 11. A secondary electric wire 14 is wound (e.g., winding 14 and/or coil 14) around at least a part of core 11. The primary electric current 15 within conductor 13 induces magnetic flux within core 11, which induces a secondary electric current in secondary wire 14. The secondary electric current may be provided to an electric circuitry 16.

It is appreciated the purpose of core 11 is to carry magnetic flux induced by an electric current flowing in electric conductor 13. Core 11 may therefore be made, for example, from a material having relatively high magnetic permeability such as iron. However, it is appreciated that any material or combination of materials that may be adequate and/or useful for the purpose and/or applications as described herein are contemplated. For example, amorphous metals and/or magnetic alloys such as Metglas available from Metglas Inc., 440 Allied Drive, Conway, S.C. 29526, USA. Therefore, the term ‘core’ in this document refers to any such device, made from an adequate material, and configured to be closed around an electric conductor configure to carry electric current.

Electric circuitry 16 may configured to operate on the electric power harvested from the primary electric current 15 via secondary winding 14. Alternatively, or additionally, electric circuitry 16 may be configured to measure the primary electric current 15 via secondary winding 14. Alternatively, or additionally, electric circuitry 16 may be configured to induce an electronic communication signal (e.g., PLC) via secondary winding 14 into conductor 13. Similar other applications are also contemplated.

It is appreciated that there may be any number of winding 14, for example, for different purposes as explained above. Such plurality of winding 14 may be placed in various places over core 11

As shown in FIG. 1, core 11 may have two or more parts to enable mounting core 11 on conductor 13, for example, after conductor 13 is installed and connected at both ends (not shown in FIG. 1). As shown in FIG. 1, when mounted on conductor 13, core 11 is closed in the shape of a ring around conductor 13. It is appreciated that core 11 may have any shape enabling conductor 13 to pass there through. The core 11 FIG. 1 includes a first part 17 and a second part 18 connected by an axle 19.

It is appreciated that instead of axle 19 is not essential, and that the parts of core 11 may be positioned together around the electric conductor without using an axle. Alternatively, for example, each part of core 11 may be contained in a container and the axle may be part of the containers rather than the core. For example, the core 11 may have more than two parts. For example, the core 11 may have two axles, each at each end of part 18, and two rotating parts such as part 17. It is appreciated that any arrangement for mounting and/or closing a core around an electric conductor is contemplated.

When the core 11 is mounted and closed around conductor 13 carrying electric current 15 the core 11 magnetized and the two parts 17 and 18 are held together firmly at the opening 20. This magnetic force may prevent demounting core 11 from conductor 13 as long as conductor 13 carries high electric current 15. It is appreciated that when mounting core 11 on conductor 13, and/or dismounting core 11 from conductor 13, opening 20 should be wide enough to allow the conductor 13 to pass there through. It is appreciated that when core 11 is closed around conductor 13, opening 20 is firmly and/or tightly closed to allow magnetic flux to flow there through.

To enable demounting core 11 from conductor 13 while carrying high electric current 15 switch 12 may be closed to provide short-circuit over winding 14 and thus reduce the magnetism of core 11 and enable the opening of core 11. It is appreciated that opening of core 11 may involve parting and/or detaching and/or separating and/or disengaging the two or more parts of core 11.

As shown in FIG. 1, switch 12 provides short-circuit of winding 14 which is also used for an application such as power harvesting, current measurement, and/or PLC. However, it is appreciated that alternatively or additionally, switch 12 provides short-circuit of an additional winding. In such embodiment, for example, a first winding is connected to switch 12 to enable opening of the core 11 for demounting the device from the conductor 13 while the electric current is flowing through the conductor 13, and a different, second, winding is connected to electric circuitry 16, for example, for measuring electric current flowing through conductor 13, and/or for harvesting electric power electric current flowing through conductor 13, and/or for inducing electric signal into conductor 13. As described above, any number of winding is contemplated.

Switch 12 may be operated manually, directly, by pressing or turning the switch. Alternatively or additionally, as shown in FIG. 1, switch 12 may be operated indirectly using an actuator 21 (e.g., an electromechanical actuator such as a solenoid actuator) connected to a manually operated switch or a controller 22 remotely operated, for example, using an RF signal.

It is appreciated that a device such as a spring or an electromechanical actuator may be added to device 10, such as about the axle 19, to assist in closing and/or opening the two parts of the core 11. It is appreciated that a controller such as controller 22 may be operative to synchronize the operation of switch 12 (such as by controlling the operation of actuator 21, with the operation of the electromechanical actuator operative to open (and/or close) the two parts of core 11.

It is appreciated that alternatively, or additionally, if a plurality of windings, such as winding 14, are provided (as described above) a corresponding plurality of switches, such as switch 12, may be provided, where each such switch may provide a short circuit of a corresponding winding. In an embodiment contemplated herein, where a plurality of windings (such as winding 14) is provided on core 11, each and every one of the winding includes a switch (such as switch 12) configured to provide a short circuit of the corresponding winding.

It is appreciated that the operation of these switches may be coordinated. For example, controller 22 may be operative to synchronize the operation of the plurality of switches 12 for example by controlling the operation of a respective plurality of actuators 21, as well as controlling the operation of an actuator closing and/or opening core 11. It is appreciated that instead of a plurality of switches it is possible to use a single switching device including a plurality of contactors.

It is appreciated that certain features of the invention, which are, described in the context of different embodiments, may also be provided in combination in a single embodiment. Conversely, various features of the invention, which are, for brevity, described in the context of a single embodiment, may also be provided separately or in any suitable sub-combination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. In addition, citation or identification of any reference in this application shall not be construed as an admission that such reference is available as prior art to the present invention.

What is claimed is:

1. A device comprising:
a core comprising at least two parts, said two parts being operative to close said core around an electric conductor passing there through;
a coil of electric wire wrapped around at least one part of said core, said coil comprising two terminals, each at one end of said coil; and
a switch, electrically coupled to said two terminals, said switch being operative to provide a short circuit of said coil upon demand;
wherein mounting said device on said electric conductor comprises closing said two parts of said core around said electric conductor while said switch is open; and
wherein demounting said device from said electric conductor comprises closing said switch to enable said two parts of said core to disengage from each other.

2. The device of claim 1 wherein said demounting of said core from said electric conductor is operative while said electric conductor carries electric current.

3. The device of claim 1 wherein said core is made of a material selected from: iron and a magnetic permeable material.

4. The device of claim 1 wherein at least one of said core and said coil is operative for at least one of:
measuring electric current via said coil;
measuring current in said electric conductor;
supplying electric power to an electric device, said electric power being drawn from said magnetic field of said electric conductor; and
inducing an electronic signal into said electric conductor.

5. The device of claim 1 wherein said coil is a plurality of coils mounted on said core; and wherein said switch is electrically coupled to said terminals of at least one coil of said plurality of coils.

6. The device of claim 1 wherein said coil is a plurality of coils mounted on said core; and wherein said switch is electrically coupled to said terminals of all said coils of said plurality of coils.

7. The device of claim 1 wherein said coil is a plurality of coils mounted on said core; and additionally comprising a plurality of coils, wherein each of said coils is electrically coupled to said terminals of a respective coil of said plurality of coils.

8. A method for demounting a device mounted on an electric conductor carrying electric current, said device being operative to provide electric current from magnetic field of said electric conductor, the method comprising:
providing said device comprising:
a core comprising at least two parts, said two parts being operative to close said core around an electric conductor passing there through;
a coil of electric wire wrapped around at least one part of said core, said coil comprising two terminals, each at one end of said coil; and
a switch, electrically coupled to said two terminals, said switch being operative to provide a short circuit of said coil upon demand;
mounting said device on said electric conductor comprises by closing said two parts of said core to form a ring around said electric conductor while said switch is open; and
demounting said device from said electric conductor comprising closing said switch to enable said two parts of said core to disengage from each other.

9. The method of claim 8 wherein said demounting said core from said electric conductor is operative while said electric conductor carries electric current.

10. The method of claim 8 wherein said core is made of a material selected from: iron and a magnetic permeable material.

11. The method of claim 8 additionally comprising at least one of:
measuring electric current via said coil.
measuring current in said electric conductor;
supplying electric power to an electric device, said electric power being drawn from said magnetic field of said electric conductor; and
inducing an electronic signal into said electric conductor.

12. The method of claim 8 wherein said device comprises:
a plurality of coils mounted on said core; and
a switch, electrically coupled to said terminals of at least one coil of said plurality of coils.

13. The method of claim 8 wherein said device comprises:
a plurality of coils mounted on said core; and
a switch, electrically coupled to said terminals of all said coils of said plurality of coils; and
wherein mounting said device on said electric conductor comprises by closing said two parts of said core to form a ring around said electric conductor while said switch is open; and
wherein demounting said device from said electric conductor comprising closing said switch to enable said two parts of said core to disengage from each other.

14. The method of claim 8 wherein said device comprises:
a plurality of coils mounted on said core; and
a plurality of coils, wherein each of said coils is electrically coupled to said terminals of a respective coil of said plurality of coils; and
wherein mounting said device on said electric conductor comprises by closing said two parts of said core to form a ring around said electric conductor while said switches are open; and
wherein demounting said device from said electric conductor comprising closing said switches to enable said two parts of said core to disengage from each other.
